(19) United States
(12) Patent Application Publication
(10) Pub. No.: US 2017/0371213 A1
(43) Pub. Date: Dec. 28, 2017

(54) ARRAY SUBSTRATE AND DRIVE METHOD THEREOF, DISPLAY PANEL AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Lei WANG, Beijing (CN); Yingming LIU, Beijing (CN); Xiaochuan CHEN, Beijing (CN); Changfeng LI, Beijing (CN); Ming YANG, Beijing (CN); Zhenhua LV, Beijing (CN)

(73) Assignees: BOE Technology Group Co.,Ltd., Beijing (CN); Beijing BOE Optoelectronics Technology Co., Ltd., Beijing (CN)

(21) Appl. No.: 15/540,450

(22) PCT Filed: Jan. 25, 2016
(86) PCT No.: PCT/CN2016/072013

§ 371 Date: Jun. 28, 2017

(30) Foreign Application Priority Data
Aug. 28, 2015 (CN) 201510543990.8

(51) Int. Cl. G02F 1/1343; G06F 3/044; H01L 27/12; G02F 1/1362

(52) U.S. Cl. CPC G02F 1/134336; G02F 1/136277; G06F 3/044; G02F 1/1362; H01L 27/1259; G02F 2001/134345; G02F 2001/136222

(57) ABSTRACT

An array substrate and drive method thereof, a display panel and a display device. The array substrate includes: a base substrate; and a plurality of pixel units and a plurality of fingerprint identifying units located on the base substrate; each pixel unit including a plurality of sub-pixel units with color filters of different colors. Orthogonal projections of sub-pixel units on the base substrate and orthogonal projections of fingerprint identifying units on the base substrate are arranged in an matrix. The array substrate can prevent interference between the fingerprint recognition signal and the display signal.

### TECHNICAL FIELD

Embodiments of the present disclosure relate to an array substrate, a driving method thereof, a display panel and a display device

### BACKGROUND

Fingerprints are inherent, unique and unchanged characteristics of a human body which can be differentiated from other people, the fingerprints are constituted by a series of ridges and valleys on the skin surface of a finger end, and composition details of these ridges and valleys decide uniqueness of fingerprint patterns. A fingerprint identifying element developed therefrom is used for personal authentication, and the fingerprint identifying element that is widely applied and well known is a capacitive type fingerprint identifying element.

An existing capacitive type fingerprint identifying element is applied to a display panel and is generally realized by additionally increasing a fingerprint identifying element in the display panel, and such fingerprint identifying element, for example, comprises a fingerprint identifying electrode and a signal line electrically connected thereto. When a finger makes contact with the display panel on which the fingerprint identifying element is integrated, a capacitance between the valleys of the finger and the fingerprint identifying electrode is different from that between the ridges of the finger and the fingerprint identifying electrode, magnitudes of sensing currents coupled by the two capacitances are different, and the fingerprint patterns of the finger can be obtained by detecting the sensing current on a signal line corresponding to each fingerprint identifying electrode.

In the display panel on which the fingerprint identifying element is integrated, a fingerprint identifying signal loaded on the newly added signal line will interfere with an original display signal in the display panel, and quality of a display picture and fingerprint identifying precision will be affected

### SUMMARY

An embodiment of the present disclosure provides an array substrate, comprising: a base substrate; and a plurality of pixel units and a plurality of fingerprint identifying units located on the base substrate. Each pixel unit includes a plurality of sub-pixel units with color filters of different colors. Orthogonal projections of sub-pixel units on the base substrate and orthogonal projections of fingerprint identifying units on the base substrate are arranged in an matrix; in a display period, a scanning signal is loaded in sequence by taking a gate line electrically connected to a row of sub-pixel units in the matrix and a fingerprint identifying scan line electrically connected to the fingerprint identifying units located in the same row as the sub-pixel units as a unit, and a gray level signal is loaded to a data line electrically connected to each column of sub-pixel units and a fingerprint identifying read line electrically connected to each column of fingerprint identifying units; in a fingerprint identify period, an electric signal is loaded to each gate line to enable the sub-pixel units electrically connected to each gate line to be in a closed state, a scanning signal is sequentially loaded to each fingerprint identifying scan line, a fingerprint identifying signal is loaded to the fingerprint identifying unit electrically connected to the fingerprint identifying scan line by each fingerprint identifying read line, and a current signal transmitted on each fingerprint identifying read line and incurred by coupling of the fingerprint identifying unit to the fingerprint identifying signal is detected.

In one optional example, the fingerprint identifying units and the sub-pixel units are located in different columns of the matrix.

In one optional example, one column of fingerprint identifying units is disposed every other column of pixel units.

In one optional example, each fingerprint identifying unit includes a fingerprint identifying electrode and a first thin film transistor; and each sub-pixel unit includes a pixel electrode and a second thin film transistor; and the fingerprint identifying electrode and the pixel electrode are disposed on a same layer.

In one optional example, each fingerprint identifying unit includes a fingerprint identifying electrode and a first thin film transistor; and each sub-pixel unit includes a pixel electrode and a second thin film transistor; and the first thin film transistor and the second thin film transistor are disposed on a same layer.

In one optional example, the fingerprint identifying scan line and the gate line are disposed on a same layer; and each fingerprint identifying scan line is in a region between adjacent rows where the fingerprint identifying units electrically connected to the fingerprint identifying scan lines are located.

In one optional example, the fingerprint identifying read line and the data line are disposed on a same layer; and each fingerprint identifying read line is located in a region between adjacent columns where the fingerprint identifying units electrically connected to the fingerprint identifying read lines are located.

In one optional example, a plurality of adjacent fingerprint identifying units are multiplexed into one self-capacitive touch unit; and in a touch period, an electric signal is loaded to each gate line to enable the sub-pixel units electrically connected to each gate line to be in a closed state, a scanning signal is sequentially loaded by taking a plurality of fingerprint identifying scan lines electrically connected to one row of self-capacitive touch units in the matrix as a unit, a touch driving signal is loaded to the fingerprint identifying unit electrically connected to the plurality of fingerprint identifying scan lines by each fingerprint identifying read line, and a current signal transmitted on each fingerprint identifying read line and incurred by coupling of the fingerprint identifying unit to the touch driving signal is detected.

An embodiment of the present disclosure provides a display panel, comprising any one of the above-described the array substrates.

In one optional example, the display panel according to the above embodiment of the present disclosure further comprises: an opposed substrate opposite to the array substrate, and a color filter layer located on one side of the array substrate facing the opposed substrate or located on one side of the opposed substrate facing the array substrate. A region corresponding to each fingerprint identifying unit in the color filter layer being transparent; or a color of the region corresponding to each fingerprint identifying unit in the color filter layer being yellow.

An embodiment of the present disclosure provides a display device, comprising: any one of the above-mentioned display panel.

An embodiment of the present disclosure provides a driving method for any one of the array substrates, comprising: in a display period, loading a scanning signal in sequence by taking a gate line electrically connected to a row of sub-pixel units in the matrix and a fingerprint identifying scan line electrically connected to the fingerprint identifying units located in the same row as the sub-pixel units as a unit, and loading a gray level signal to a data line electrically connected to each column of sub-pixel units and a fingerprint identifying read line electrically connected to each column of fingerprint identifying units; in a fingerprint identify period, loading an electric signal to each gate line to enable the sub-pixel units electrically connected to each gate line to be in a closed state, sequentially loading a scanning signal to each fingerprint identifying scan line, loading a fingerprint identifying signal to the fingerprint identifying unit electrically connected to the fingerprint identifying scan line by each fingerprint identifying read line, and detecting a current signal transmitted on each fingerprint identifying read line and incurred by coupling of the fingerprint identifying unit to the fingerprint identifying signal.

In one optional example, the method further comprises: in a touch period, loading an electric signal to each gate line to enable the sub-pixel units electrically connected to each gate line to be in a closed state, sequentially loading a scanning signal by taking a plurality of fingerprint identifying scan lines electrically connected to one row of self-capacitive touch units in the matrix as a unit, loading a touch driving signal to the fingerprint identifying unit electrically connected to the plurality of fingerprint identifying scan lines by each fingerprint identifying read line, and detecting a current signal transmitted on each fingerprint identifying read line and incurred by coupling of the fingerprint identifying unit to the touch driving signal.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 and FIG. 2 are structural schematic diagrams of an array substrate provided by an embodiment of the present disclosure, respectively;

FIG. 3 is a first flow chart of a driving method for an array substrate provided by an embodiment of the present disclosure;

FIG. 4 is a driving time sequence diagram of an array substrate provided by an embodiment of the present disclosure; and

FIG. 5 is a second flow chart of a driving method for an array substrate provided by an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Shapes and sizes of respective components in the drawings do not reflect a true proportion, and are merely intended to schematically explain contents of embodiments of the present disclosure.

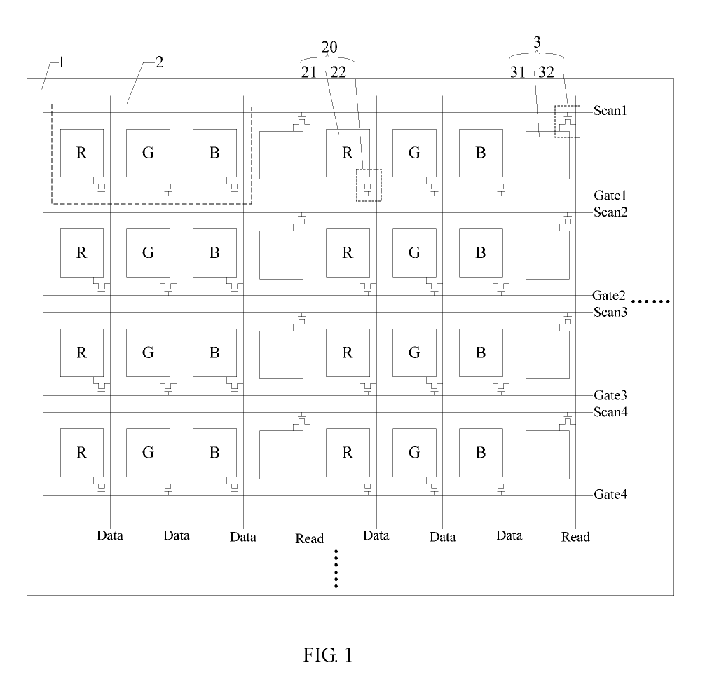

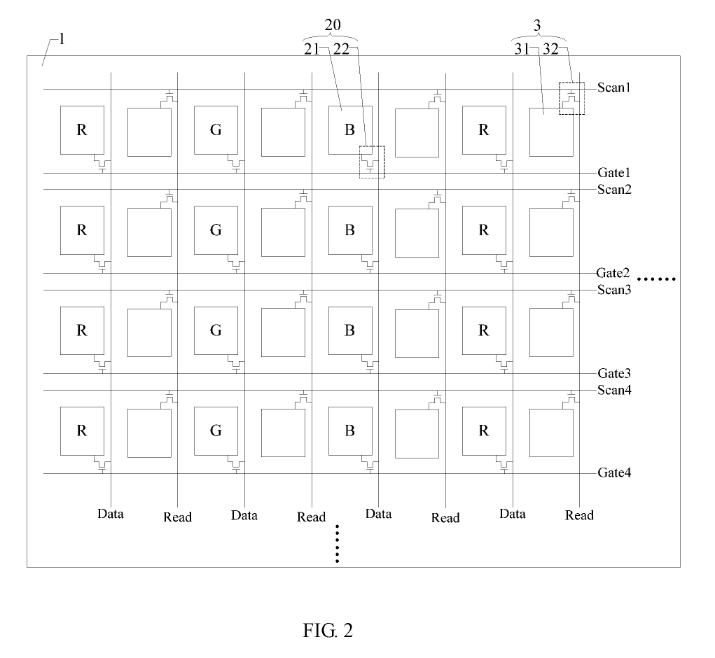

An array substrate provided by an embodiment of the present disclosure, as illustrated in FIGS. 1 and 2, comprises a base substrate 1 and a plurality of pixel units 2 and a plurality of fingerprint identifying units 3 located on the base substrate 1; each pixel unit 2 includes a plurality of sub-pixel units with color filters of different colors; and FIG. 1 takes each pixel unit 2 which comprises three sub-pixel units, for which the colors of color filters are Red (R), green (G) and blue (B), as an example for explanation.

Orthogonal projections of the sub-pixel units 20 on the base substrate 1 and orthogonal projections of fingerprint identifying units 3 on the base substrate 1 are arranged in a matrix.

In a display period, a scanning signal is loaded in sequence by taking a gate line Gate electrically connected to a row of sub-pixel units 20 in the matrix and a fingerprint identifying scan line Scan electrically connected to the fingerprint identifying units 3 located in the same row as the sub-pixel units as a unit, and a gray level signal is loaded to a data line Data electrically connected to each column of sub-pixel units 20 and a fingerprint identifying read line Read electrically connected to each column of fingerprint identifying units 3. For example, as illustrated in FIGS. 1 and 2, in a first scanning period of one frame display time, a high level signal is loaded to the gate line Gate1 electrically connected to a first row of sub-pixel units 20 in the matrix and the fingerprint identifying scan line Scan1 electrically connected to the fingerprint identifying units 3 (the first row of fingerprint identifying units as illustrated in FIGS. 1 and 2) located in the same row as the first row of sub-pixel units 20, and a low-level signal is loaded to other gate lines and other fingerprint identifying scan lines, and a gray level signal is loaded to each data line Data and each fingerprint identifying read line Read; in a second scan period of such frame display time, a high level signal is loaded to the gate line Gate2 electrically connected to a second row of sub-pixel units 20 in the matrix and the fingerprint identifying scan line Scan2 electrically connected to the fingerprint identifying units 3 (the second row of fingerprint identifying units as illustrated in FIGS. 1 and 2) located in the same row as the second row of sub-pixel units 20, and a low-level signal is loaded to other gate lines and other fingerprint identifying scan lines, and a gray level signal is loaded to each data line Data and each fingerprint identifying read line Read; and so on;

In a fingerprint identify period, an electric signal is loaded to each gate line Gate to enable the sub-pixel units 20 electrically connected to each gate line Gate to be in a closed state, a scanning signal is sequentially loaded to each fingerprint identifying scan line Scan, a fingerprint identifying signal is loaded to the fingerprint identifying unit 3 electrically connected to the fingerprint identifying scan line Scan by each fingerprint identifying read line Read, and a current signal transmitted over each fingerprint identifying read line Read and incurred by coupling of the fingerprint identifying unit 3 to the fingerprint identifying signal is detected.

In the above assay substrate provided by the embodiment of the present disclosure, because the orthogonal projections of the sub-pixel units on the base substrate and the orthogonal projections of the fingerprint identifying units on the base substrate are arranged in a matrix, a time-sharing driving manner can be adopted when the array substrate is driven: in the display period, the fingerprint identifying units are multiplexed to be a sub-pixel unit to display a picture, i.e., a scanning signal is loaded in sequence by taking a gate line electrically connected to a row of sub-pixel units in the matrix and a fingerprint identifying scan line electrically connected to the fingerprint identifying units located in the same row as the sub-pixel units as a unit, and a gray level signal is loaded to a data line electrically connected to each column of sub-pixel units and a fingerprint identifying read line electrically connected to each column of fingerprint identifying units; in the fingerprint identify period, all sub-pixels are in a closed state, only the fingerprint identifying signal is loaded to respective rows of fingerprint identifying units row by row, and a current signal transmitted over each fingerprint identifying read line and incurred by coupling of the fingerprint identifying unit to the fingerprint identifying signal is detected to perform identifying of fingerprint patterns; hence, the problem of mutual interference between the fingerprint identifying signal and a display signal can be avoided.

Preferably, in the above array substrate provided by the embodiment of the present disclosure, as illustrated in FIGS. 1 and 2, the fingerprint identifying units 3 and the sub-pixel units 20 are located in different columns of the matrix, that is, one or more columns of fingerprint identifying units are disposed every other one column or more columns of sub-pixel units. For example, as illustrated in FIG. 1, one column of fingerprint identifying units 3 are disposed every other three columns of sub-pixel units 20; or as illustrated in FIG. 2, one column of fingerprint identifying units 3 are disposed every other one column of sub-pixel units 20. Thus, precision of fingerprint identifying in a column direction of the matrix can be unified, and therefore, the sensitivity of the array substrate for realizing the fingerprint identifying can be improved.

Further, in the above array substrate provided by the embodiment of the present disclosure, as illustrated in FIG. 1, one column of fingerprint identifying units 3 are disposed every other one column of pixel units 2 (i.e., three columns of sub-pixel units 20), thus, the precision of fingerprint identifying in a row direction of the matrix can be unified, and therefore, the sensitivity of the array substrate for realizing the fingerprint identifying can be further improved. In a specific implementation, the density of the fingerprint identifying units can be set according to a fingerprint identifying precision, for example, as illustrated in FIG. 2, one column of fingerprint identifying units 3 can be disposed every other one column of sub-pixel units 20, which is not limited herein.

For example, as illustrated in FIGS. 1 and 2, each fingerprint identifying unit 3 comprises a fingerprint identifying electrode 31 and a first thin film transistor 32; and each sub-pixel unit 20 comprises a pixel electrode 21 and a second thin film transistor 22. For example, as illustrated in FIGS. 1 and 2, a gate electrode of the first thin film transistor 32 is electrically connected to the fingerprint identifying scan line Scan electrically connected to the fingerprint identifying unit 3 to which the first thin film transistor belongs, a source electrode of the first thin film transistor 32 is electrically connected to the fingerprint identifying read line Read electrically connected to the fingerprint identifying unit 3 to which the first thin film transistor belongs, and a drain electrode of the first thin film transistor 32 is electrically connected to the fingerprint identifying unit 31 in the fingerprint identifying unit 3 to which the first thin film transistor belongs; a gate electrode of the second thin film transistor 22 is electrically connected to the gate line Gate electrically connected to the sub-pixel unit 20 to which the second thin film transistor belongs, a source electrode of the second thin film transistor 22 is electrically connected to the data line Data electrically connected to the sub-pixel unit 20 to which the second thin film transistor belongs, and a drain electrode of the second thin film transistor 22 is electrically connected to the pixel electrode 21 in the sub-pixel unit 20 to which the second thin film transistor belongs. For example, in order to simplify the manufacturing process of the array substrate, in the above array substrate provided by the embodiment of the present disclosure, the fingerprint identifying electrode and the pixel electrode can be disposed on a same layer, that is, the fingerprint identifying electrode and the pixel electrode are made of a same layer of material, and are manufactured in a same one patterning process.

For example, as illustrated in FIGS. 1 and 2, each fingerprint identifying unit 3 comprises a fingerprint identifying electrode 31 and a first thin film transistor 32; and each sub-pixel unit 20 comprises a pixel electrode 21 and a second thin film transistor 22. For example, in order to simplify the manufacturing process of the array substrate, in the above array substrate provided by the embodiment of the present disclosure, the first thin film transistor and the second thin film transistor can be disposed on a same layer, that is, a gate electrode of the first thin film transistor and that of the second thin film transistor are made of a same layer of material, the two gate electrodes are manufactured by a same one patterning process, the source electrode and the drain electrode of the first thin film transistor and those of the second thin film transistor are made of a same layer of material, and the two source electrodes and drain electrodes are manufactured by a same one patterning process, an active layer of the first thin film transistor and that of the second thin film transistor are made of a same layer of material, and the two active layers are manufactured by a same one patterning process.

For example, in order to simplify the manufacturing process of the array substrate, in the above array substrate provided by the embodiment of the present disclosure, the fingerprint identifying scan line and the gate line can be disposed on a same layer, that is, the fingerprint identifying scan line and the gate line are made of a same layer of material, and the two are manufactured by a same one patterning process. Since the gate line is made of a metal material usually, in order to avoid influence on normal display caused by light leakage of each fingerprint identifying scan line, each fingerprint identifying scan line can be disposed in a region between adjacent rows where the fingerprint identifying units electrically connected to the fingerprint identifying scan lines are located, that is, the fingerprint identifying scan line is disposed in a region where the gate line is located, and thus, the fingerprint identifying scan line can be shielded by a black matrix correspondingly disposed in the region between two adjacent rows.

For example, in order to simplify the manufacturing process of the array substrate, in the above array substrate provided by the embodiment of the present disclosure, in the above array substrate provided by the embodiment of the present disclosure, the fingerprint identifying read line and the data line can be disposed on a same layer, that is, the fingerprint identifying scan line and the data line are made of a same layer of material, and the two are manufactured by a same one patterning process. Since the data line is made of a metal material usually, in order to avoid influence on normal display caused by light leakage of each fingerprint identifying read line, each fingerprint identifying read line can be disposed in a region between adjacent columns where the fingerprint identifying units electrically connected to the fingerprint identifying read lines are located, and the fingerprint identifying read line can be shielded by a black matrix correspondingly disposed in the region between two adjacent columns.

It should be noted that, the above array substrate provided by the embodiment of the present disclosure is not limited to the cases that the fingerprint identifying electrode in the fingerprint identifying unit and the pixel electrode in the sub-pixel unit are disposed on the same layer, the first thin film transistor in the fingerprint identifying unit and the second thin film transistor in the sub-pixel unit are disposed on the same layer, the fingerprint identifying scan line and the gate line are disposed on the same layer and the fingerprint identifying read line and the data line are disposed on the same layer. The fingerprint identifying unit, the fingerprint identifying scan line and the fingerprint identifying read line can be disposed on a passivation layer of the array substrate, or the fingerprint identifying unit, the fingerprint identifying scan line and the fingerprint identifying read line can be disposed on one side of an opposed substrate opposite to the array substrate, which is not limited herein.

Generally, a touch precision is about 5 mm, and a precision of fingerprint identifying is about 50 μm, and therefore, in the above array substrate provided by an embodiment of the present disclosure, a plurality of adjacent fingerprint identifying units can be multiplexed to be one self-capacitive touch unit, and thus the array substrate having the fingerprint identifying function can also realize a touch function. For example, in a touch period, an electric signal is loaded to each gate line to enable the sub-pixel units electrically connected to each gate line to be in a closed state, a scanning signal is sequentially loaded by taking a plurality of fingerprint identifying scan lines electrically connected to one row of self-capacitive touch units in the matrix as a unit, a touch driving signal is loaded to the fingerprint identifying unit electrically connected to the plurality of fingerprint identifying scan lines by each fingerprint identifying read line, a current signal transmitted on each fingerprint identifying read line and incurred by coupling of the fingerprint identifying unit to the touch driving signal is detected, and then the touch function can be realized.

For example, four adjacent fingerprint identifying units can be multiplexed to be one self-capacitive touch unit, as illustrated in FIG. 2, the fingerprint identifying unit 3 located in the first row and the second column, the fingerprint identifying unit 3 located in the first row and the fourth column, the fingerprint identifying unit 3 located in the second row and the second column and the fingerprint identifying unit 3 located in the second row and the fourth column are multiplexed to be one self-capacitive touch unit. In the touch period, a low level electric signal is loaded to each gate line Gate to enable the sub-pixel unit 20 electrically connected to each gate line to be in a closed state, a touch driving signal is sequentially loaded by taking two adjacent fingerprint identifying scan lines Scan as a unit, the touch driving signal is loaded to the fingerprint identifying unit 3 electrically connected to the two fingerprint identifying scan lines by each fingerprint identifying read line Read, a current signal transmitted over each fingerprint identifying read line Read and incurred by coupling of the fingerprint identifying unit to the touch driving signal is detected, and then the touch function can be realized.

An embodiment of the present disclosure further provides a display panel, comprising the above array substrate provided by the embodiment of the present disclosure. Implementation of the display panel can refer to the embodiment of the array substrate above and is not repeated.

For example, the display panel provided by the embodiment of the present disclosure further comprises: an opposed substrate opposite to the array substrate and a color filter layer located on one side of the array substrate facing the opposed substrate or located on one side of the opposed substrate facing the array substrate. A fingerprint detecting unit occupies locations of the sub-pixel units, and therefore, the fingerprint detecting unit may affect an aperture ratio of the display panel. On this basis, in the above display panel provided by the embodiment of the present disclosure, a region corresponding to each fingerprint identifying unit in the color filter layer can be set to be transparent; or a color of a region corresponding to each fingerprint identifying unit in the color filter layer can be set to be yellow; hence, light transmittance of the display panel can be improved, and therefore, the influence of the fingerprint detection unit on the aperture ratio of the display panel can be compensated, and display quality of the display panel is improved.

An embodiment of the present disclosure further provides a display device, comprising the display panel provided by the embodiment of the present disclosure. The display device can be any product or component having a display function, such as a cellphone, a tablet computer, a television, a display, a laptop, a digital photoframe and a navigator, and implementation of the display device can refer to the embodiment of the above display panel, and is not repeated.

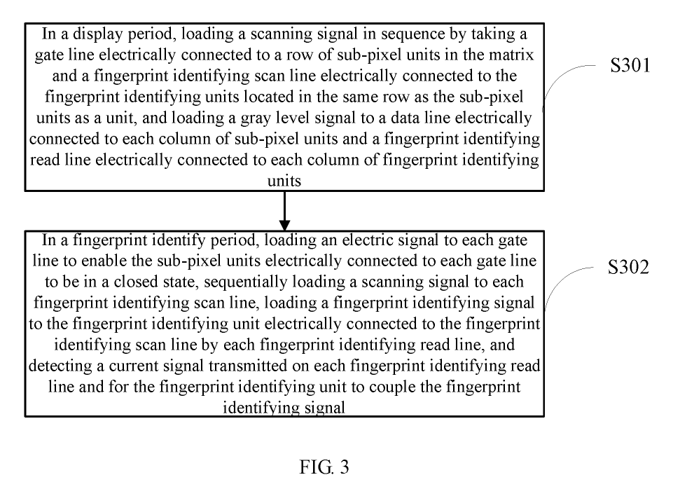

With respect to the array substrate provided by an embodiment of the present disclosure, the embodiment of the present disclosure further provides a driving method for the array substrate, which, as illustrated in FIG. 3, comprises the following operations:

S301: in a display period, loading a scanning signal in sequence by taking a gate line electrically connected to a row of sub-pixel units in the matrix and a fingerprint identifying scan line electrically connected to the fingerprint identifying units located in the same row as the sub-pixel units as a unit, and loading a gray level signal to a data line electrically connected to each column of sub-pixel units and a fingerprint identifying read line electrically connected to each column of fingerprint identifying units;

S302: in a fingerprint identify period, loading an electric signal to each gate line to enable the sub-pixel units electrically connected to each gate line to be in a closed state, sequentially loading a scanning signal to each fingerprint identifying scan line, loading a fingerprint identifying signal to the fingerprint identifying unit electrically connected to the fingerprint identifying scan line by each fingerprint identifying read line, and detecting a current signal transmitted on each fingerprint identifying read line and incurred by coupling of the fingerprint identifying unit to the fingerprint identifying signal.

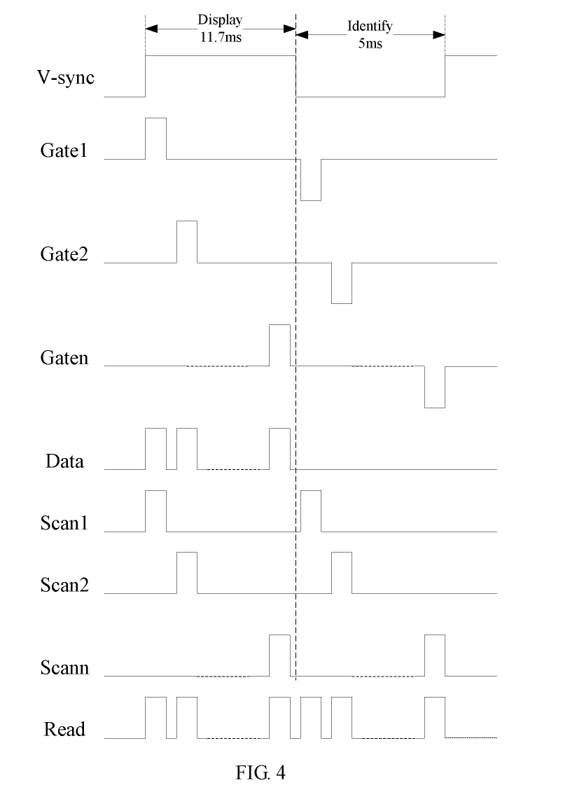

For example, in a driving time sequence diagram of FIG. 4, the time for displaying each frame (V-sync) is divided into a display period (Display) and a fingerprint identify period (Identify). For example, in a driving time sequence diagram of FIG. 4, time for displaying each frame is 16.7 ms, of which 5 ms is selected as the fingerprint identify period and the rest 11.7 ms serve as the display period; of course, the two durations can be properly adjusted according to the processing capacity of a driving chip, and are not limited herein. In the display period (Display), a scanning signal is loaded to the gate line Gate1 and the fingerprint identifying scan line Scan1, the gate line Gate2 and the fingerprint identifying scan line Scan2 . . . , and the gate line Gaten and the fingerprint identifying scan line Scann in sequence, and a gray level signal is loaded to each data line Data and each fingerprint recognizing read line Read to realize a display function. In the fingerprint identify period, a low level electric signal is loaded to each gate line Gate1, Gate2 Gaten to enable each sub-pixel unit to be in a closed state, a scanning signal is loaded to each fingerprint identifying scan line Scan1, Scan2 . . . Scann in sequence, a fingerprint identifying signal is loaded to the fingerprint identifying unit electrically connected to the fingerprint identifying scan line by each fingerprint identifying read line Read, and a current signal transmitted over each fingerprint identifying read line Read and incurred by coupling of the fingerprint identifying unit to the touch driving signal is detected to realize a fingerprint identifying function.

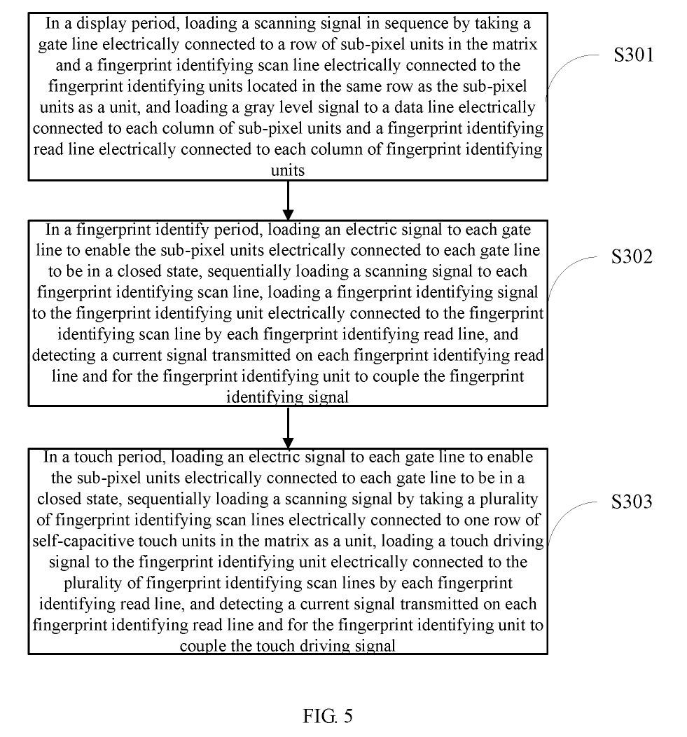

For example, the method provided by the embodiment of the present disclosure, as illustrated in FIG. 5, can further comprise the following step:

S303: in a touch period, loading an electric signal to each gate line to enable the sub-pixel units electrically connected to each gate line to be in a closed state, sequentially loading a scanning signal by taking a plurality of fingerprint identifying scan lines electrically connected to one row of self-capacitive touch units in the matrix as a unit, loading a touch driving signal to the fingerprint identifying unit electrically connected to the plurality of fingerprint identifying scan lines by each fingerprint identifying read line, and detecting a current signal transmitted on each fingerprint identifying read line and incurred by coupling of the fingerprint identifying unit to the touch driving signal.

The embodiments of the present disclosure provide an array substrate, a driving method thereof, a display panel and a display device; in such array substrate, since the orthogonal projection of each sub-pixel unit on the base substrate and the orthogonal projection of each fingerprint identifying unit on the base substrate are arranged in matrix, a time-sharing driving manner can be adopted when the array substrate is driven: in the display period, the fingerprint identifying units are multiplexed to be a sub-pixel unit display picture; in the fingerprint identify period, all sub-pixels are in a closed state, the fingerprint identifying signal is only loaded to respective rows of fingerprint identifying units row by row, and a current signal transmitted on each fingerprint identifying read line and incurred by coupling of the fingerprint identifying unit to the fingerprint identifying signal is detected to perform identifying of fingerprint patterns; hence, the problem of mutual interference between the fingerprint identifying signal and a display signal can be avoided.

The foregoing embodiments merely are exemplary embodiments of the disclosure, and not intended to define the scope of the disclosure, and the scope of the disclosure is determined by the appended claims.

The application claims priority of Chinese Patent Application No. 201510543990.8 filed on Aug. 28, 2015, the disclosure of which is incorporated herein by reference in its entirety as part of the present application.

1. An array substrate, comprising:
a base substrate; and
a plurality of pixel units and a plurality of fingerprint identifying units located on the base substrate; each pixel unit including a plurality of sub-pixel units with color filters of different colors, wherein
orthogonal projections of sub-pixel units on the base substrate and orthogonal projections of fingerprint identifying units on the base substrate are arranged in an matrix;
in a display period, a scanning signal is loaded in sequence by taking a gate line electrically connected to a row of sub-pixel units in the matrix and a fingerprint identifying scan line electrically connected to the fingerprint identifying units located in the same row as the sub-pixel units as a unit, and a gray level signal is loaded to a data line electrically connected to each column of sub-pixel units and a fingerprint identifying read line electrically connected to each column of fingerprint identifying units;
in a fingerprint identify period, an electric signal is loaded to each gate line to enable the sub-pixel units electrically connected to each gate line to be in a closed state, a scanning signal is sequentially loaded to each fingerprint identifying scan line, a fingerprint identifying signal is loaded to the fingerprint identifying unit electrically connected to the fingerprint identifying scan line by each fingerprint identifying read line, and a current signal transmitted on each fingerprint identifying read line and incurred by coupling of the fingerprint identifying unit to the fingerprint identifying signal is detected.

2. The array substrate according to claim 1, wherein the fingerprint identifying units and the sub-pixel units are located in different columns of the matrix.

3. The array substrate according to claim 2, wherein one column of fingerprint identifying units is disposed every other column of pixel units.

4. The array substrate according to claim 1, wherein each fingerprint identifying unit includes a fingerprint identifying electrode and a first thin film transistor; and each sub-pixel unit includes a pixel electrode and a second thin film transistor; and
the fingerprint identifying electrode and the pixel electrode are disposed on a same layer.

5. The array substrate according to claim 1, wherein each fingerprint identifying unit includes a fingerprint identifying electrode and a first thin film transistor; and each sub-pixel unit includes a pixel electrode and a second thin film transistor; and
the first thin film transistor and the second thin film transistor are disposed on a same layer.

6. The array substrate according to claim 1, wherein the fingerprint identifying scan line and the gate line are disposed on a same layer; and
each fingerprint identifying scan line is in a region between adjacent rows where the fingerprint identifying units electrically connected to the fingerprint identifying scan lines are located.

7. The array substrate according to claim 1, wherein the fingerprint identifying read line and the data line are disposed on a same layer; and
each fingerprint identifying read line is located in a region between adjacent columns where the fingerprint identifying units electrically connected to the fingerprint identifying read lines are located.

8. The array substrate according to claim 1, wherein a plurality of adjacent fingerprint identifying units are multiplexed into one self-capacitive touch unit; and
in a touch period, an electric signal is loaded to each gate line to enable the sub-pixel units electrically connected to each gate line to be in a closed state, a scanning signal is sequentially loaded by taking a plurality of fingerprint identifying scan lines electrically connected to one row of self-capacitive touch units in the matrix as a unit, a touch driving signal is loaded to the fingerprint identifying unit electrically connected to the plurality of fingerprint identifying scan lines by each fingerprint identifying read line, and a current signal transmitted on each fingerprint identifying read line and incurred by coupling of the fingerprint identifying unit to the touch driving signal is detected.

9. A display panel, comprising: the array substrate according to claim 1.

10. The display panel according to claim 9, further comprising:
an opposed substrate opposite to the array substrate, and
a color filter layer located on one side of the array substrate facing the opposed substrate or located on one side of the opposed substrate facing the array substrate;
wherein a region corresponding to each fingerprint identifying unit in the color filter layer being transparent; or a color of the region corresponding to each fingerprint identifying unit in the color filter layer being yellow.

11. A display device, comprising: the display panel according to claim 9.

12. A driving method for the array substrate according to claim 1, comprising:
in a display period, loading a scanning signal in sequence by taking a gate line electrically connected to a row of sub-pixel units in the matrix and a fingerprint identifying scan line electrically connected to the fingerprint identifying units located in the same row as the sub-pixel units as a unit, and loading a gray level signal to a data line electrically connected to each column of sub-pixel units and a fingerprint identifying read line electrically connected to each column of fingerprint identifying units;
in a fingerprint identify period, loading an electric signal to each gate line to enable the sub-pixel units electrically connected to each gate line to be in a closed state, sequentially loading a scanning signal to each fingerprint identifying scan line, loading a fingerprint identifying signal to the fingerprint identifying unit electrically connected to the fingerprint identifying scan line by each fingerprint identifying read line, and detecting a current signal transmitted on each fingerprint identifying read line and incurred by coupling of the fingerprint identifying unit to the fingerprint identifying signal.

13. The method according to claim 12, further comprising:
in a touch period, loading an electric signal to each gate line to enable the sub-pixel units electrically connected to each gate line to be in a closed state, sequentially loading a scanning signal by taking a plurality of fingerprint identifying scan lines electrically connected to one row of self-capacitive touch units in the matrix as a unit, loading a touch driving signal to the fingerprint identifying unit electrically connected to the plurality of fingerprint identifying scan lines by each fingerprint identifying read line, and detecting a current signal transmitted on each fingerprint identifying read line and incurred by coupling of the fingerprint identifying unit to the touch driving signal.

14. The array substrate according to claim 2, wherein each fingerprint identifying unit includes a fingerprint identifying electrode and a first thin film transistor; and each sub-pixel unit includes a pixel electrode and a second thin film transistor; and
the fingerprint identifying electrode and the pixel electrode are disposed on a same layer.

15. The array substrate according to claim 2, wherein each fingerprint identifying unit includes a fingerprint identifying electrode and a first thin film transistor; and each sub-pixel unit includes a pixel electrode and a second thin film transistor; and
the first thin film transistor and the second thin film transistor are disposed on a same layer.

16. The array substrate according to claim 2, wherein the fingerprint identifying scan line and the gate line are disposed on a same layer; and
each fingerprint identifying scan line is in a region between adjacent rows where the fingerprint identifying units electrically connected to the fingerprint identifying scan lines are located.

17. The array substrate according to claim 2, wherein the fingerprint identifying read line and the data line are disposed on a same layer; and
each fingerprint identifying read line is located in a region between adjacent columns where the fingerprint identifying units electrically connected to the fingerprint identifying read lines are located.

18. The array substrate according to claim 2, wherein a plurality of adjacent fingerprint identifying units are multiplexed into one self-capacitive touch unit; and
in a touch period, an electric signal is loaded to each gate line to enable the sub-pixel units electrically connected to each gate line to be in a closed state, a scanning signal is sequentially loaded by taking a plurality of fingerprint identifying scan lines electrically connected to one row of self-capacitive touch units in the matrix as a unit, a touch driving signal is loaded to the fingerprint identifying unit electrically connected to the plurality of fingerprint identifying scan lines by each fingerprint identifying read line, and a current signal transmitted on each fingerprint identifying read line and incurred by coupling of the fingerprint identifying unit to the touch driving signal is detected.

19. A driving method for the array substrate according to claim 8, comprising:
in a display period, loading a scanning signal in sequence by taking a gate line electrically connected to a row of sub-pixel units in the matrix and a fingerprint identifying scan line electrically connected to the fingerprint identifying units located in the same row as the sub-pixel units as a unit, and loading a gray level signal to a data line electrically connected to each column of sub-pixel units and a fingerprint identifying read this electrically connected to each column of fingerprint identifying units;
in a fingerprint identify period, loading an electric signal to each gate line to enable the sub-pixel units electrically connected to each gate line to be in a closed state, sequentially loading a scanning signal to each fingerprint identifying scan line, loading a fingerprint identifying signal to the fingerprint identifying unit electrically connected to the fingerprint identifying scan line by each fingerprint identifying read line, and detecting a current signal transmitted on each fingerprint identifying read line and incurred by coupling of the fingerprint identifying unit to the fingerprint identifying signal.

20. The method according to claim 19, further comprising:
in a touch period, loading an electric signal to each gate line to enable the sub-pixel units electrically connected to each gate line to be in a closed state, sequentially loading a scanning signal by taking a plurality of fingerprint identifying scan lines electrically connected to one row of self-capacitive touch units in the matrix as a unit, loading a touch driving signal to the fingerprint identifying unit electrically connected to the plurality of fingerprint identifying scan lines by each fingerprint identifying read line, and detecting a current signal transmitted on each fingerprint identifying read line and incurred by coupling of the fingerprint identifying unit to the touch driving signal.
